(19) United States
(12) Patent Application Publication
(10) Pub. No.: US 2026/0244239 A1
(43) Pub. Date: Aug. 20, 2026

(54) METHOD, APPARATUS, DEVICE, AND STORAGE MEDIUM FOR EVALUATING CLOCK TREE

(71) Applicant: Beijing Youzhuju Network Technology Co., Ltd., Beijing (CN)

(72) Inventors: Shanguo WEI, Beijing (CN); Jiale LIU, Beijing (CN); Jian WANG, Beijing (CN)

(21) Appl. No.: 19/470,800

(22) PCT Filed: Apr. 1, 2024
(86) PCT No.: PCT/CN2024/085390

§ 371 Date: Sep. 29, 2025

(30) Foreign Application Priority Data
Apr. 6, 2023 (CN) 202310362046.7

(51) Int. Cl. G06F 1/10

(52) U.S. Cl. CPC G06F 1/10

(57) ABSTRACT

According to the embodiments of the disclosure, a method, an apparatus, a device, and a storage medium for evaluating a clock tree are provided. In a method, a candidate clock tree structure for a clock tree is automatically determined based on a set of structural parameters for a plurality of portions of the clock tree, each structural parameter of the set of structural parameters being configured to define a structure of one of the plurality of portions; circuit configuration information associated with the candidate clock tree structure is obtained, the circuit configuration information indicating connection relationships of circuit units in the candidate clock tree structure; and a clock performance of the candidate clock tree structure is determined based at least on the circuit configuration information.

The present application claims priority to Chinese Patent Application No. 202310362046.7, filed on Apr. 6, 2023, and entitled “METHOD, APPARATUS, DEVICE, AND STORAGE MEDIUM FOR EVALUATING CLOCK TREE”, which is incorporated herein by reference in its entirety.

### FIELD

Example embodiments of the present disclosure generally relate to the field of integrated circuits, and in particular, to a method, an apparatus, a device, and a computer-readable storage medium for evaluating a clock tree.

### BACKGROUND

A clock tree is a structure of a clock distribution network, and is used to transmit a clock signal to various timing elements. A process of generating a clock tree according to a constraint requirement of a clock network is referred to as clock tree synthesis (CTS). Clock tree synthesis is a very important step in a back-end design process of a digital circuit. Goals of clock tree synthesis include how to reduce clock skew, reduce on-chip variation (OCV), and increase driving strength.

### SUMMARY

In a first aspect of the present disclosure, a method for evaluating a clock tree is provided. The method includes: automatically determining a candidate clock tree structure for a clock tree based on a set of structural parameters for a plurality of portions of the clock tree, each structural parameter of the set of structural parameters being configured to define a structure of one of the plurality of portions; obtaining circuit configuration information associated with the candidate clock tree structure, the circuit configuration information indicating connection relationships of circuit units in the candidate clock tree structure; and determining a clock performance of the candidate clock tree structure based at least on the circuit configuration information.

In a second aspect of the present disclosure, an apparatus for evaluating a clock tree is provided. The apparatus includes: a clock tree structure determining module configured to automatically determine a candidate clock tree structure for a clock tree based on a set of structural parameters for a plurality of portions of the clock tree, each structural parameter of the set of structural parameters being configured to define a structure of one of the plurality of portions; a circuit configuration information obtaining module configured to obtain circuit configuration information associated with the candidate clock tree structure, the circuit configuration information indicating connection relationships of circuit units in the candidate clock tree structure; and a clock performance determining module configured to determine a clock performance of the candidate clock tree structure based at least on the circuit configuration information.

In a third aspect of the present disclosure, an electronic device is provided. The device includes at least one processing unit; and at least one memory coupled to the at least one processing unit and storing instructions for execution by the at least one processing unit. The instructions, when executed by the at least one processing unit, cause the device to perform the method according to the first aspect.

In a fourth aspect of the present disclosure, a computer-readable storage medium is provided. A computer program is stored on the computer-readable storage medium, and the computer program is executable by a processor to implement the method according to the first aspect.

It should be understood that the content described in this Summary section is not intended to identify key features or essential features of the embodiments of the present disclosure, nor is it intended to limit the scope of the present disclosure. Other features of the present disclosure will be readily apparent from the following description.

### BRIEF DESCRIPTION OF THE DRAWINGS

The above and other features, advantages, and aspects of the embodiments of the present disclosure will become more apparent when taken in conjunction with the drawings and with reference to the following detailed description. In the drawings, the same or similar reference numerals refer to the same or similar elements, where:

FIG. 1 illustrates a schematic diagram of an example environment in which embodiments of the present disclosure may be implemented;

FIG. 2 illustrates a schematic diagram of an example of a clock tree according to some embodiments of the present disclosure;

FIG. 3 illustrates a flowchart of an example process of clock tree design according to some embodiments of the present disclosure;

FIG. 4 illustrates a flowchart of an example process of clock tree evaluation according to some embodiments of the present disclosure;

FIG. 5 illustrates a flowchart of a method for evaluating a clock tree according to some embodiments of the present disclosure;

FIG. 6 illustrates a block diagram of an apparatus for evaluating a clock tree according to some embodiments of the present disclosure; and

FIG. 7 illustrates a block diagram of a device capable of implementing a plurality of embodiments of the present disclosure.

### DETAILED DESCRIPTION

It should be understood that before the technical solutions disclosed in the embodiments of the present disclosure are used, the user should be informed of the type, use scope, and use scenario of the personal information involved in the present disclosure through an appropriate manner according to relevant laws and regulations, and the user's authorization should be obtained.

For example, in response to receiving an active request from the user, prompt information is sent to the user to explicitly prompt the user that the operation requested to be performed will require the acquisition and use of the user's personal information. Thus, the user may autonomously select whether to provide personal information to software or hardware, such as an electronic device, an application, a server, or a storage medium, that performs the operation of the technical solution of the present disclosure according to the prompt information.

As an optional but non-limiting implementation, the manner of sending the prompt information to the user in response to receiving the active request from the user may be, for example, a pop-up window, and the prompt information may be presented in the pop-up window in the form of text. In addition, the pop-up window may also carry a selection control for the user to select “agree” or “disagree” to provide personal information to the electronic device.

It should be understood that the above process of notifying and obtaining user authorization is only illustrative, and does not constitute a limitation to the implementations of the present disclosure. Other manners that satisfy relevant laws and regulations may also be applied to the implementations of the present disclosure.

It should be understood that the data involved in the technical solution (including but not limited to the data itself, the acquisition or use of the data) should comply with the requirements of relevant laws and regulations and related provisions.

The term “in response to” as used herein represents a state in which a corresponding event occurs, or a condition is satisfied. It will be appreciated that the timing of the subsequent action performed in response to the event or condition is not necessarily strongly related to the time at which the event occurs, or the condition is established. For example, in some cases, the subsequent action may be performed immediately when the event occurs or the condition is established; while in other cases, the subsequent action may be performed after a period of time after the event occurs or the condition is established.

The embodiments of the present disclosure will be described in more detail below with reference to the drawings. Although some embodiments of the present disclosure are shown in the drawings, it should be understood that the present disclosure may be implemented in various forms and should not be interpreted as limited to the embodiments set forth herein. On the contrary, these embodiments are provided for a more thorough and complete understanding of the present disclosure. It should be understood that the drawings and embodiments of the present disclosure are only for illustrative purposes, and are not intended to limit the protection scope of the present disclosure.

It should be noted that the titles of any sections/subsections provided herein are not limiting. Various embodiments are described throughout this document, and any type of embodiment may be included under any section/subsection. Furthermore, the embodiments described in any section/subsection may be combined in any manner with any other embodiments described in the same section/subsection and/or different sections/subsections.

In the description of the embodiments of the present disclosure, the term “include/comprise” and similar terms should be understood as open-ended inclusions, that is, “include/comprise but not limited to”. The term “based on” should be understood as “based at least in part on”. The term “an embodiment” or “the embodiment” should be understood as “at least one embodiment”. The term “some embodiments” should be understood as “at least some embodiments”. Other explicit and implicit definitions may be included below. The terms “first”, “second”, etc. may refer to different or the same objects. Other explicit and implicit definitions may be included below.

As used herein, the term “clock tree structure” or similar terms refer to a specific structure of an instantiated clock network.

In an integrated circuit (for example, a chip), the clock performance of a clock tree is crucial to the operation of various components in the integrated circuit. Therefore, in the design of the integrated circuit, it is expected to design a clock tree structure, or a clock tree instance, with excellent clock performance. A clock tree has different structural parameters, and different parameter values of the same structural parameter may cause relatively large differences in clock performance. In the process of clock tree design or clock tree instantiation, it will be beneficial to understand the impact of changes in structural parameters on clock performance.

A relatively high requirement is imposed on the designers in terms of clock tree structure design experience in the implementation of the entire process from clock tree design to verification (also referred to as evaluation). The entire process involves many design and simulation tools, and the automation of the process is relatively complicated.

To this end, the embodiments of the present disclosure provide a solution for evaluating a clock tree. According to various embodiments of the present disclosure, a candidate clock tree structure for a clock tree is automatically determined based on a set of structural parameters for a plurality of portions of the clock tree, each structural parameter of the set of structural parameters is configured to define a structure of one of the plurality of portions. Circuit configuration information associated with the candidate clock tree structure is obtained, and the circuit configuration information indicates the connection relationship of circuit units in the candidate clock tree structure. The clock performance of the candidate clock tree structure is determined based at least on the circuit configuration information. In this manner, automation of clock tree design, evaluation, or verification may be achieved from the structural parameters of the clock tree. In this way, by changing the value of the structural parameter, the impact of different structural parameters on the clock performance may be quickly and comprehensively understood. This may facilitate the implementation of an excellent clock tree design and optimization process.

The example embodiments of the present disclosure will be described below with reference to the drawings.

### Example Environment and Example Clock Tree

FIG. 1 illustrates a schematic diagram of an example environment 100 in which embodiments of the present disclosure may be implemented. In the environment 100, the electronic device 120 obtains a set of structural parameters 110 for a plurality of portions of a clock tree. Each structural parameter in the set of structural parameters 110 is configured to define a structure of one of the plurality of portions. In the set of structural parameters 110, each structural parameter may have one or more parameter values.

In some embodiments, parameter values of at least some structural parameters in the set of structural parameters 110 may be automatically generated by the electronic device 110. Alternatively, or additionally, in some embodiments, parameter values of one or more structural parameters in the set of structural parameters 110 may be specified or customized by a user (for example, a designer). For example, the electronic device 120 may provide a user interface for receiving the user's customization of one or more structural parameters in the set of structural parameters 110.

The electronic device 120 automatically completes the design and simulation verification of the clock tree based on a combination of structural parameters in the set of structural parameters 110. Further, the electronic device 120 outputs an evaluation result 130 of the clock tree. The evaluation result may include clock performance of various designed clock tree instances, such as a delay on one or more clock propagation paths, a clock skew, and the like.

In some embodiments, for different clock tree structures (also referred to as clock tree instances), the process of simulation verification may be automatically iterated. For example, in the case where a plurality of combinations of structural parameters may be determined based on the set of structural parameters 110, each combination may define a clock tree structure. Further, simulation verification may be performed for each clock tree structure.

It should be understood that the structure and function of the environment 100 are described for illustrative purposes only, without implying any limitation to the scope of the present disclosure.

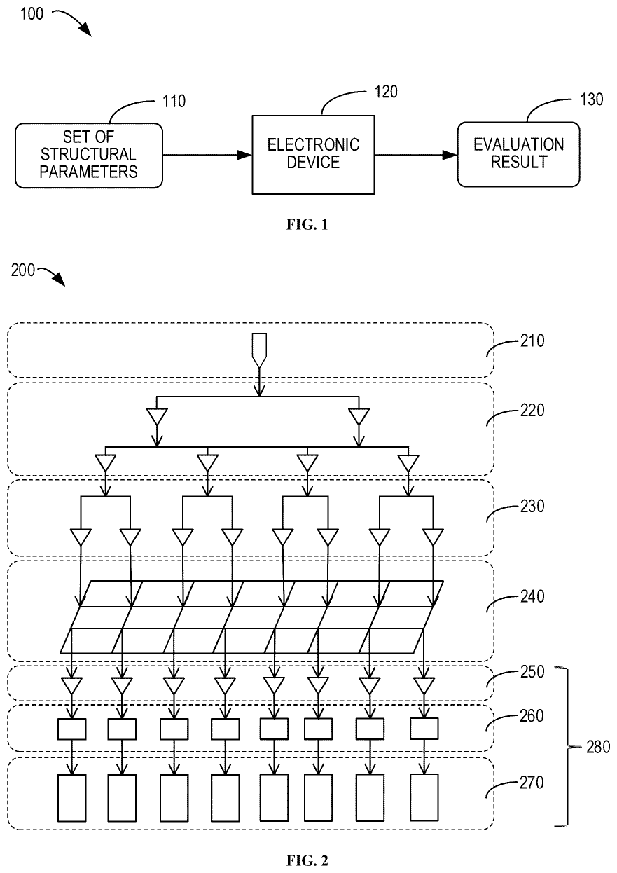

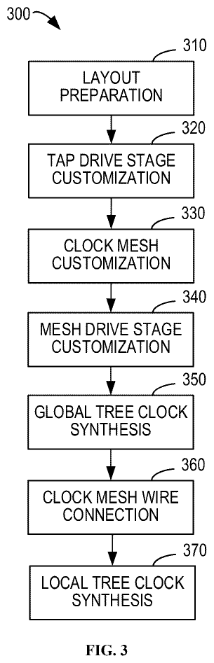

The electronic device 120 may design and simulate any appropriate type of clock tree. In some embodiments, the clock tree may include a clock mesh. In order to better understand the embodiments of the present disclosure, a type of clock tree is described below as an example with reference to FIG. 2.

FIG. 2 illustrates a schematic diagram of an example clock tree 200 according to some embodiments of the present disclosure. The clock tree 200 includes a clock source 210, a global tree 220, a mesh drive stage 230, a clock mesh 240, and a local tree 280. The local tree 280 may further include a tap drive stage 250, a gating unit 260, and a timing unit 270. The clock tree 200 is configured to provide a clock signal to the timing unit 270 (such as a register or a memory) and minimize the difference in the time signal transmitted to each timing unit 270. The timing unit 270 may be regarded as a unit that uses a clock signal in an integrated circuit, and may also be referred to as a load.

The clock source 210 is configured to generate a clock signal, which includes elements that may actively emit a clock signal (such as an active crystal oscillator or a passive crystal oscillator). Since different timing units 270 have different requirements for clock frequencies, the clock source 210 may further include an element for multiplying the clock signal (such as a phase-locked loop) or an element for dividing the clock signal (such as a frequency divider). In some embodiments, the clock source 210 may be a clock input port for introducing a clock signal from a top-level chip.

The global tree 220 is configured to transmit a clock signal emitted by the clock source 210 with a small clock skew. The global tree 220 includes a plurality of drivers (such as buffers or inverters). These drivers may be arranged in a tree structure (such as a binary tree or an H-tree), a fishbone structure, or other structures.

The mesh drive stage 230 is configured to drive the clock mesh 240. The mesh drive stage 230 includes a plurality of drivers (such as buffers or inverters).

The clock mesh 240 is configured to transmit a clock signal to the timing unit 270. The clock mesh 240 is a mesh structure formed by short-circuiting some clock signal nodes together, which may reduce the difference in the clock signal transmitted to each timing unit 270. Metal wires constituting the mesh structure are connected at intersections through vias.

The tap drive stage 250 is configured to couple the clock mesh 240 to the timing unit 270. The coupling manner may be direct coupling or coupling through a tree structure.

The gating unit 260 is configured to turn on and off the clock signal of each timing unit 270. Cutting off the clock signal when the timing unit 270 is not working helps to reduce the dynamic power consumption of the chip.

The global tree 220 is a common part on a clock path, and may distribute the clock signal to the entire clock region, thereby solving the problem of a large fan-out and a large load in the clock network. The local tree 280 is a non-common part on the clock path, and has a small interconnection range.

The example clock tree 200 described with reference to FIG. 2 is a structurally multi-source clock tree, which reduces on-chip variation (OCV) impact and improves clock tree performance compared with a traditional clock tree. For this type of clock tree, the user has great freedom in design. For example, aspects such as the global tree, the clock mesh, the mesh drive stage, and the tap drive stage may be customized according to the user. However, the local tree is based on register transfer level (RTL), and thus the instantiation of the clock tree is relatively limited. The local tree may integrate and split the clock logic units in the clock tree synthesis stage, without changing its logic level and clock structure.

In the following, this type of clock tree will mainly be described as an example, but it should be understood that this is only illustrative and is not intended to limit the solutions of the present disclosure. The embodiments of the present disclosure are applicable to any appropriate type of clock tree.

### Clock Tree Design

In the design stage of the clock tree, the electronic device 120 automatically determines a candidate clock tree structure for the clock tree based on a set of structural parameters for a plurality of portions of the clock tree. The set of structural parameters includes a plurality of structural parameters for defining various portions of the clock tree. For example, the plurality of portions may be the global tree 220, the mesh drive stage 230, the clock mesh 240, and the tap drive stage 250 described above with reference to FIG. 2. The structural parameters may include, but are not limited to, the number of buffer units in each portion, and the position in the integrated circuit. For the clock mesh, the structural parameters may include parameters of a pattern of the clock mesh, as will be described below.

In some embodiments, at least one structural parameter in the set of structural parameters may be automatically set by the electronic device 120. For example, for a certain structural parameter, the electronic device 120 may automatically select one or more parameter values from a set of candidate parameter values to configure the structural parameter. For another example, the electronic device 120 may perform interval sampling within a possible value range of the parameter value, to determine a plurality of parameter values, and configure the structural parameter with these parameter values.

Alternatively, or additionally, in some embodiments, at least one structural parameter in the set of structural parameters may be customized by the user. Specifically, the electronic device 120 may provide a user interface for structure configuration, and receive at least one parameter in the set of structural parameters via the user interface. The parameter customized by the user may correspond to at least one portion of the clock tree. In particular, in this way, the customization of the corresponding unit may be achieved.

In some embodiments, the structure of one or more of the clock mesh 240, the mesh drive stage 230, and the tap drive stage 250 may be customized by the user. For example, the electronic device 120 may provide a user interface for the mesh drive stage 230. Accordingly, the user may specify the number and position distribution of respective buffer units in the mesh drive stage 230 via the interface. Alternatively, or additionally, the electronic device 230 may provide a user interface for the tap drive stage 250. Accordingly, the user may specify the number and position distribution of respective buffer units in the tap drive stage 250 via the interface. Alternatively, or additionally, a user interface for the mesh drive stage 230 may be provided. Accordingly, the user may specify a pattern of the clock mesh 240 via the interface.

FIG. 3 illustrates a flowchart of an example process 300 of clock tree design according to some embodiments of the present disclosure. The process 300 is described by taking the clock tree 200 shown in FIG. 2 as an example, but this is only illustrative. The concept of the clock tree design described with reference to FIG. 3 is also applicable to other types of clock trees.

At block 310, the electronic device 120 obtains a database. In the database, all placement operations have been completed, including the placement and addition of required components. For example, the placement of the clock unit and the logic unit has been completed, the physical unit and the power supply solution in the previous stage have been added, and so on.

The clock unit includes the clock source 210 and drivers at various levels. The clock source 210 may be referred to as a root node. The timing unit 270 may be referred to as a sink point. The clock signal travels from the clock source 210 through a series of distribution nodes and finally reaches the timing unit 270. The physical unit includes a unit without a logic function, such as a unit for reducing noise. At block 310, the electronic device 120 is ready for the basic conditions for normal clock tree synthesis.

At block 320, the electronic device 120 performs customization of the tap drive stage. Specifically, one or more structural parameter values of the tap drive stage 250 specified by the user may be received. For example, the user may reasonably select the number and position of the tap drivers (for example, buffer units) according to the distribution of the sink points. The electronic device 120 receives, through the user interface, the structural parameter of the tap drive stage 250, such as the number and position of the buffer units in the tap drive stage 250. For example, an interface for defining the structure of the tap drive stage may be opened to the user, and then processing is automatically performed according to the user's input. Alternatively, or additionally, in some embodiments, the electronic device 120 may configure a given number of buffer units at corresponding positions based on an average distribution mode. In some embodiments, two modes of user customization and automatic distribution may be supported, or one of the modes may be selected or enabled by the user.

At block 330, the electronic device 120 performs customization of the clock mesh. Specifically, the electronic device 120 may receive one or more structural parameter values of the clock mesh 240 specified by the user. For example, the user may design the clock mesh 240 according to specific parameters and analysis results and in conjunction with resource considerations. The electronic device 120 receives, through the user interface, the structural parameters of the clock mesh 240, such as a wiring width, a wiring spacing, a pattern spacing, an offset, and so on. The wiring width refers to the width of the metal wires constituting the mesh structure. The wiring spacing refers to the distance between the metal wires constituting the mesh structure. The pattern spacing refers to the distance between different patterns in the mesh. The offset refers to the movement of the mesh relative to a reference position. The user may customize an optimized design solution according to specific parameters and analysis of results and in conjunction with resource considerations.

At block 340, the electronic device 120 performs customization of the mesh drive stage. Specifically, the electronic device 120 may receive one or more structural parameter values of the mesh drive stage 230 specified by the user. For example, the user may design the mesh drive stage 230, such as the number and position of buffer units, according to the required driving capability and the structure of the clock mesh 240. The electronic device 120 receives, through the user interface, the structural parameters of the mesh drive stage 230, such as the number and position of the buffer units in the mesh drive stage 230. In some embodiments, the electronic device 120 receives the parasitic electrical parameter in the clock mesh 240, such as parasitic capacitance and resistance of the wiring, for correcting on-chip variation. The number and position of the buffer units may be reasonably designed in conjunction with the parasitic electrical parameters (such as parasitic capacitance and resistance) and simulation results.

At block 350, the electronic device 120 designs the global tree 220. For example, the user may specify a network structure of the global tree 220, such as an H-tree or a traditional clock tree synthesis, while ensuring that the mesh drive stage 230 may be driven. The electronic device 120 may insert a buffer and route the clock signal based on the network structure, to generate the global tree 220. Additionally, or alternatively, the electronic device 120 may add a ground wire for shielding interference, to prevent other signal lines from parasitic interference with the network structure. For example, the ground wire may be added according to a non-default rule to ensure the clock tree performance.

At block 360, the electronic device 120 performs wire connection for the clock mesh 240. For example, the electronic device 120 connects the input and output of the clock mesh 240 in close proximity. Specifically, the output end of the clock mesh 240 is connected to the tap drive stage 250, and the input end of the clock mesh 240 is connected to the mesh drive stage 230. Further, the global tree 220 and the local tree 280 upstream and downstream of the clock mesh 240 may be combined and connected.

At block 370, the electronic device 120 performs structure generation of the local tree 280. For example, the electronic device 120 may integrate or split the gating unit 260 to connect to the buffer unit in the tap drive stage 250. Further, the electronic device 120 may perform clock tree synthesis based on this. Alternatively, processing may also be customized by the user according to a specific clock tree structure.

In conclusion, the electronic device 120 may receive the user's free customization of the plurality of portions of the clock tree, and automatically generate the clock tree structure based on the structure parameter set customized by the user. For example, through design optimization, the user may be helped quickly implement parameter customization of the clock mesh pattern (for example, width, spacing, etc.), the mesh driver (for example, position, number, etc.), and the tap driver (for example, position, number, etc.) to design different clock tree structures, thereby optimizing the performance parameters of the clock tree.

In the example process described above with reference to FIG. 3, an interface for structural parameter definition is provided for the user's customization requirements. In this manner, the operation may be automatically performed according to the structural parameters defined by the user. This may advantageously avoid human interference.

### Clock Tree Evaluation

When evaluating the clock performance of a clock tree, for different clock tree structures, especially for structures including a clock mesh, parasitic parameters need to be extracted for simulating the clock tree structure. Traditional static timing analysis tools may not directly perform static timing analysis on the clock tree including a clock mesh, thus some embodiments of the present disclosure provide a solution for this defect.

The electronic device 120 first automatically generates the clock tree structure based on the set of structural parameters 110, such as described with reference to FIG. 3. Then, the electronic device 120 generates circuit configuration information associated with the clock tree structure. The circuit configuration information indicates connection relationships of circuit units in the clock tree structure. Then, the electronic device 120 performs simulation and optimization on the clock tree structure based on the circuit configuration information. Finally, the evaluation result 130 of the clock performance of the clock tree structure is output.

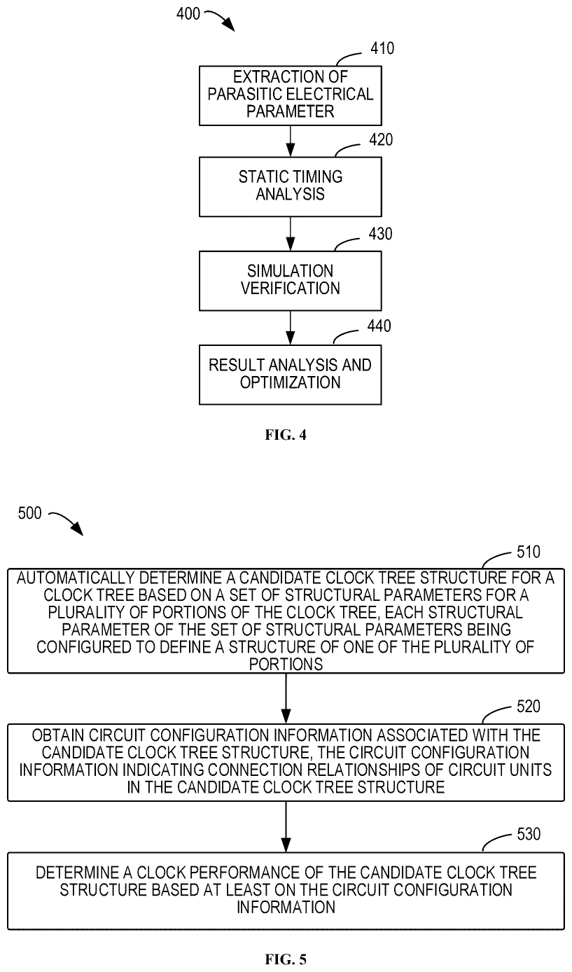

FIG. 4 illustrates a flowchart of an example process 400 of clock tree evaluation according to some embodiments of the present disclosure. The process 400 is described by taking the clock tree 200 shown in FIG. 2 as an example, but this is only illustrative. The concept of the clock tree verification described with reference to FIG. 4 is also applicable to other types of clock trees.

At block 410, the electronic device 120 extracts parasitic electrical parameters of the clock tree 200. Since the clock mesh 240 has a plurality of driving sources, the electronic device 120 extracts parasitic electrical parameters (such as a parasitic resistance, a parasitic capacitance, etc.) of the entire clock network. For example, after the design of the clock tree 200 is completed, the electronic device 120 derives a designed exchange format file and a netlist. The exchange format file contains position distributions and wiring information of various portions of the clock tree. The electronic device 120 extracts the parasitic electrical parameters from the exchange format file, and outputs a parasitic electrical parameter file. In some embodiments, the electronic device 120 only extracts the parasitic electrical parameters of the clock mesh 240, so as to reduce the amount of computation and improve the evaluation efficiency.

At block 420, the electronic device 120 performs static timing analysis on the clock tree 200. Electrical configuration information (which indicates the connection relationship of circuit units in the designed clock tree structure) may be obtained through the static timing analysis. As an example, if SPICE simulation is used for subsequent simulation verification, an input for the SPICE simulation process may be generated. For example, the static timing analysis process may be implemented or embedded into an input generation system of the SPICE simulation environment.

At block 430, the electronic device 120 performs simulation verification on the clock tree 200. For example, the electronic device 120 performs the simulation verification of the clock tree 200 based at least on the parasitic electrical parameters and the electrical configuration information. The input of the simulation verification may further include a simulation mode and the like, depending on a specific simulation environment used.

The evaluation result of the clock performance of the clock tree structure may be obtained through the simulation. The evaluation result may include a path delay, a clock propagation latency, a clock skew, a clock transition time, a clock uncertainty, the number of levels of the clock, and so on.

In some embodiments, the automation of the clock tree design, the extraction of parasitic electrical parameter, static timing analysis, and simulation verification may be achieved, which not only solves the problem of complex cooperation of a plurality of tools in the traditional design-to-verification process, but also solves the problem that the traditional static timing analysis tool may not perform static analysis on the clock tree including the clock mesh.

Blocks 410, 420, and 430 in the process 400 may be performed for each clock tree structure (also referred to as a candidate clock tree structure) obtained or designed in the process 300, to obtain the clock performance of each clock tree structure. For example, the above process may be automatically iterated for different user customized structures. In this automated iteration, no manual intervention is required.

In some embodiments, the electronic device 120 determines a plurality of clock tree structures based on a plurality of structural parameter combinations, respectively. For example, the electronic device 120 receives parameter values of a wiring position and a wiring width of the clock mesh 240, and parameter values of the number of the mesh drive stage 230 and the number of the tap drive stage 250, which are input by the user. The electronic device 120 combines these parameters to determine a plurality of clock tree structures separately, and then outputs the evaluation result for each clock tree structure. For example, blocks 410, 420, and 430 are performed for each clock tree structure.

In some embodiments, at block 440, the electronic device 120 may further analyze and optimize the simulation results of each clock tree structure. As mentioned above, a plurality of different clock tree structures may be obtained by customizing different parameters, and after blocks 410 to 430 are automatically performed, a simulation result may be obtained for each clock tree structure (or each set of structural parameters). By analyzing and comparing these simulation results, the optimized structural parameters may be obtained.

In some embodiments, the electronic device 120 may present an interface of the evaluation result 130 or provide a user interface for outputting the evaluation result 130 to the user. The evaluation result 130 includes the clock performance determined for the plurality of clock tree structures separately.

Table 1 to Table 4 show evaluation results of the clock tree structure according to some embodiments of the present disclosure. In this example, the set of structural parameters may include the wiring spacing and the wiring width of the clock mesh 240, and the number of buffer units in the tap drive stage 250 and the number of buffer units in the mesh drive stage 230. The electronic device 120 generates various clock tree structures and their evaluation results 130 based on the combinations of these structural parameters. The evaluation result 130 includes the longest path delay and the shortest path delay from the clock source 210 to the timing unit 270. The difference between the longest path delay and the shortest path delay is the clock skew. According to the clock domain and path relationship, the clock skew may be divided into a global skew and a local skew. The global skew refers to the maximum deviation between any two path delays in the same clock domain. The local skew refers to the maximum deviation between any two path delays with a logical association in the same clock domain. Taking the global skew as an example, the evaluation results in Table 1 to Table 4 are compared.

Table 1 shows the impact of the change in the wiring width of the clock mesh 240 on the global skew when the wiring spacing of the clock mesh 240, the number of buffer units in the tap drive stage 250, and the number of buffer units in the mesh drive stage 230 remain unchanged. Each row represents a kind of clock tree structure. It may be seen that the narrower the wiring width is, the smaller the global skew is.

TABLE 1
Evaluation results of the clock tree structure based
on a first set of structural parameter combinations

| | | | | | Number | Number |
|---|---|---|---|---|---|---|
| Wiring | Wiring | Shortest | Longest | Global | of tap | of mesh |
| spacing | width | path | path | skew | drive | drive |
| (μm) | (μm) | delay (ns) | delay (ns) | (ps) | stages | stages |
| 229.824 | 0.248 | 0.2960 | 0.3029 | 6.9 | 20 | 20 |
| 229.824 | 0.124 | 0.2927 | 0.2994 | 6.7 | 20 | 20 |
| 229.824 | 0.062 | 0.2917 | 0.2975 | 5.8 | 20 | 20 |

The difference between Table 2 and Table 1 lies in that the number of buffer units in the mesh drive stage 230 is adjusted from 20 to 30. By comparing Table 2 and Table 1, it may be seen that the more the number of the mesh drive stage 230 is, the smaller the global skew is.

TABLE 2
Evaluation results of the clock tree structure based
on a second set of structural parameter combinations

| | | | | | Number | Number |
|---|---|---|---|---|---|---|
| Wiring | Wiring | Shortest | Longest | Global | of tap | of mesh |
| spacing | width | path | path | skew | drive | drive |
| (μm) | (μm) | delay (ns) | delay (ns) | (ps) | stages | stages |
| 229.824 | 0.248 | 0.3441 | 0.3478 | 3.7 | 20 | 30 |
| 229.824 | 0.124 | 0.3436 | 0.3475 | 3.9 | 20 | 30 |
| 229.824 | 0.062 | 0.3462 | 0.3421 | 4.1 | 20 | 30 |

The difference between Table 3 and Table 1 lies in that the wiring spacing of the clock mesh 240 is adjusted from 229.824 μm to 114.912 μm. By comparing Table 3 and Table 1, it may be seen that the larger the wiring spacing is, the smaller the global skew is.

TABLE 3
Evaluation results of the clock tree structure based
on a third set of structural parameter combinations

| | | | | | Number | Number |
|---|---|---|---|---|---|---|
| Wiring | Wiring | Shortest | Longest | Global | of tap | of mesh |
| spacing | width | path | path | skew | drive | drive |
| (μm) | (μm) | delay (ns) | delay (ns) | (ps) | stages | stages |
| 114.912 | 0.248 | 0.3087 | 0.3172 | 8.5 | 20 | 20 |
| 114.912 | 0.124 | 0.3022 | 0.3133 | 11.1 | 20 | 20 |
| 114.912 | 0.062 | 0.2993 | 0.3099 | 10.6 | 20 | 20 |

The difference between Table 4 and Table 3 lies in that the number of buffer units in the tap drive stage 230 is adjusted from 20 to 40. By comparing Table 4 and Table 3, it may be seen that the fewer the number of the tap drive stage 230 is, the smaller the global skew is.

TABLE 4
Evaluation results of the clock tree structure based
on a fourth set of structural parameter combinations

| | | | | | Number | Number |
|---|---|---|---|---|---|---|
| Wiring | Wiring | Shortest | Longest | Global | of tap | of mesh |
| spacing | width | path | path | skew | drive | drive |
| (μm) | (μm) | delay (ns) | delay (ns) | (ps) | stages | stages |
| 114.912 | 0.248 | 0.3230 | 0.3418 | 18.8 | 40 | 20 |
| 114.912 | 0.124 | 0.3146 | 0.3400 | 25.4 | 40 | 20 |
| 114.912 | 0.062 | 0.3092 | 0.3341 | 24.9 | 40 | 20 |

It should be understood that the data listed in Table 1 to Table 4 are only illustrative, and are not intended to limit the scope of the present disclosure.

In conclusion, according to the various embodiments of the present disclosure, the electronic device 120 may implement the customization of the plurality of portions of the clock tree based on the structure parameter set 110 input by the user, and automatically generate the plurality of clock tree structures without human intervention. The electronic device 120 may also perform the clock performance evaluation on the plurality of clock tree structures and output the evaluation result 130. In the evaluation process, the electronic device 120 automatically performs the simulation optimization, which solves the problem that the traditional static timing analysis tool may not handle the multi-drive structure of the clock mesh. Further, the electronic device 120 realizes the automation of the entire process of user customized design, extraction of parasitic electrical parameters, static timing analysis, simulation verification, and evaluation result display, which provides an excellent design optimization process for the back-end clock tree design.

In other words, the process 300 and the process 400 described above with reference to FIG. 3 and FIG. 4 may be implemented automatically. In this manner, for the clock tree, an automation solution of the entire process from design to verification and even to optimization is achieved.

### Example Process

FIG. 5 illustrates a flowchart of a method 500 for evaluating a clock tree according to some embodiments of the present disclosure. The method 500 may be implemented at the electronic device 120. The method 500 is described below with reference to FIG. 1.

At block 510, the electronic device 120 automatically determines a candidate clock tree structure for a clock tree based on a set of structural parameters for a plurality of portions of the clock tree, each structural parameter of the set of structural parameters being configured to define a structure of one of the plurality of portions. At block 520, the electronic device 120 obtains circuit configuration information associated with the candidate clock tree structure, the circuit configuration information indicating connection relationships of circuit units in the candidate clock tree structure. At block 530, the electronic device 120 determines a clock performance of the candidate clock tree structure based at least on the circuit configuration information.

In some embodiments, in order to determine the candidate clock tree structure, the electronic device 120 performs the following: in response to at least one structural parameter in the set of structural parameters having different parameter values, determining a plurality of structural parameter combinations, each structural parameter combination including a set of parameter values for defining the plurality of portions; determining a plurality of clock tree structures for the clock tree respectively based on the plurality of structural parameter combinations; and configuring the plurality of clock tree structures as the candidate clock tree structure respectively.

In some embodiments, the electronic device 120 presents the clock performance that is respectively determined for the plurality of clock tree structures.

In some embodiments, in order to determine the plurality of clock tree structures respectively, the electronic device 120 performs the following: determining, for a given structural parameter combination among the plurality of structural parameter combinations, respective structures of the plurality of portions; and determining a clock tree structure, from among the plurality of clock tree structures, that corresponds to the given structural parameter combination based on the structures of the plurality of portions and a relative relationship between the plurality of portions.

In some embodiments, the electronic device 120 performs the following: providing, for at least one portion of the plurality of portions, a user interface for structure configuration; and receiving, via the user interface, at least one parameter in the set of structural parameters, the at least one parameter corresponding to the at least one portion respectively.

In some embodiments, the at least one portion includes at least one of: a clock mesh configured to transmit a clock signal to a timing unit, a mesh drive stage configured to drive the clock mesh, or a tap drive stage configured to couple the clock mesh to the timing unit.

In some embodiments, the plurality of portions includes a clock mesh configured to transmit the clock signal to the timing unit, and in order to determine the clock performance, the electronic device 120 further performs the determination based on a parasitic electrical parameter in the candidate clock tree structure.

### Example Apparatus and Device

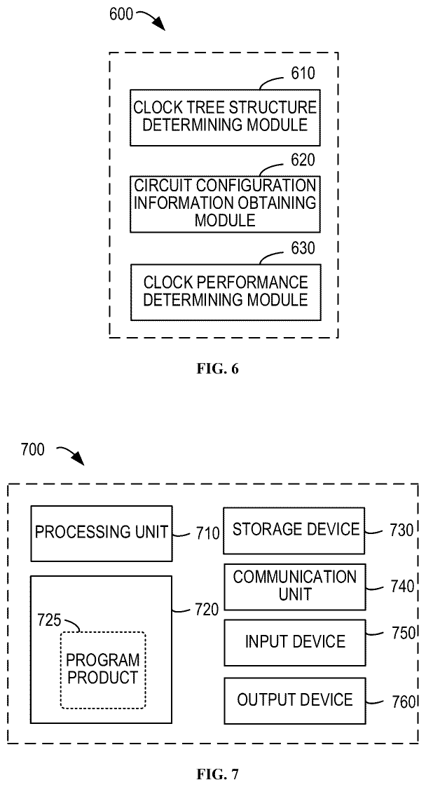

FIG. 6 illustrates a schematic structural block diagram of an apparatus 600 for evaluating a clock tree according to some embodiments of the present disclosure. The apparatus 600 may be implemented as or included in the electronic device 120. Various modules/components in the apparatus 600 may be implemented by hardware, software, firmware, or any combination thereof.

As shown in FIG. 6, the apparatus 600 includes a clock tree structure determining module 610 configured to automatically determine a candidate clock tree structure for a clock tree based on a set of structural parameters for a plurality of portions of the clock tree, each structural parameter of the set of structural parameters being configured to define a structure of one of the plurality of portions. The apparatus 600 further includes a circuit configuration information obtaining module 620 configured to obtain circuit configuration information associated with the candidate clock tree structure, the circuit configuration information indicating connection relationships of circuit units in the candidate clock tree structure. The apparatus 600 further includes a clock performance determining module 630 configured to determine a clock performance of the candidate clock tree structure based at least on the circuit configuration information.

In some embodiments, the clock tree structure determining module is configured to: in response to at least one structural parameter in the set of structural parameters having different parameter values, determine a plurality of structural parameter combinations, each structural parameter combination including a set of parameter values for defining the plurality of portions; determine, based on the plurality of structural parameter combinations, a plurality of clock tree structures for the clock tree respectively; and configure the plurality of clock tree structures as the candidate clock tree structure respectively.

In some embodiments, the apparatus 600 further includes: a clock performance presenting module configured to present the clock performance that is respectively determined for the plurality of clock tree structures.

In some embodiments, the clock tree structure determining module is further configured to: determine, for a given structural parameter combination among the plurality of structural parameter combinations, respective structures of the plurality of portions; and determine a clock tree structure, from among the plurality of clock tree structures, that corresponds to the given structural parameter combination based on the structures of the plurality of portions and relative relationships between the plurality of portions.

In some embodiments, the apparatus 600 further includes: a user interface providing module configured to provide, for at least one portion of the plurality of portions, a user interface for structure configuration; and a parameter set receiving module configured to receive, via the user interface, at least one parameter in the set of structural parameters, the at least one parameter corresponding to the at least one portion respectively.

In some embodiments, the at least one portion includes at least one of: a clock mesh configured to transmit a clock signal to a timing unit, a mesh drive stage configured to drive the clock mesh, or a tap drive stage configured to couple the clock mesh to the timing unit.

In some embodiments, the plurality of portions includes the clock mesh configured to transmit the clock signal to the timing unit, and the clock performance determining module is further configured to determine the clock performance based on the parasitic electrical parameter in the candidate clock tree structure.

FIG. 7 illustrates a block diagram of an electronic device 700 in which one or more embodiments of the present disclosure may be implemented. It should be understood that the electronic device 700 shown in FIG. 7 is only illustrative, and should not constitute any limitation to the function and scope of the embodiments described herein. The electronic device 700 shown in FIG. 7 may be configured to implement the electronic device 120 in FIG. 1.

As shown in FIG. 7, the electronic device 700 is in the form of a general-purpose electronic device. The components of the electronic device 700 may include, but are not limited to, one or more processors or processing units 710, a memory 720, a storage device 730, one or more communication units 740, one or more input devices 750, and one or more output devices 760. The processing unit 710 may be an actual or virtual processor and may perform various processing according to programs stored in the memory 720. In a multi-processor system, a plurality of processing units execute computer-executable instructions in parallel to improve the parallel processing capability of the electronic device 700.

The electronic device 700 typically includes a plurality of computer storage media. Such media may be any available media that may be accessed by the electronic device 700, including but not limited to volatile and non-volatile media, and removable and non-removable media. The memory 720 may be a volatile memory (for example, a register, a cache, a random-access memory (RAM)), a non-volatile memory (for example, a read-only memory (ROM), an electrically erasable programmable read-only memory (EEPROM), a flash memory), or some combination thereof. The storage device 730 may be a removable or non-removable medium, and may include a machine-readable medium, such as a flash drive, a disk, or any other medium, which may be configured to store information and/or data (for example, training data for training) and may be accessed within the electronic device 700.

The electronic device 700 may further include additional removable/non-removable, volatile/non-volatile storage media. Although not shown in FIG. 7, a disk drive for reading from or writing to a removable, non-volatile disk (for example, a “floppy disk”) and an optical disk drive for reading from or writing to a removable, non-volatile optical disk may be provided. In these cases, each drive may be connected to a bus (not shown) by one or more data media interfaces. The memory 720 may include a computer program product 725 having one or more program modules configured to perform various methods or actions of various embodiments of the present disclosure.

The communication unit 740 enables communication with other electronic devices through a communication medium. Additionally, the functions of the components of the electronic device 700 may be implemented by a single computing cluster or a plurality of computing machines that may communicate through communication connections. Therefore, the electronic device 700 may operate in a networked environment using logical connections with one or more other servers, network personal computers (PCs), or other network nodes.

The input device 750 may be one or more input devices, such as a mouse, a keyboard, a trackball, etc. The output device 760 may be one or more output devices, such as a display, a speaker, a printer, etc. The electronic device 700 may also communicate with one or more external devices (not shown), such as a storage device, a display device, etc., communicate with one or more devices that enable the user to interact with the electronic device 700, or communicate with any device (for example, a network card, a modem, etc.) that enables the electronic device 700 to communicate with one or more other electronic devices, through the communication unit 740 as required. Such communication may be performed via an input/output (I/O) interface (not shown).

According to an example implementation of the present disclosure, a computer-readable storage medium is provided, on which computer-executable instructions are stored, where the computer-executable instructions are executed by a processor to implement the method described above. According to an example implementation of the present disclosure, a computer program product is further provided. The computer program product is tangibly stored on a non-transitory computer-readable medium and includes computer-executable instructions, and the computer-executable instructions are executed by a processor to implement the method described above.

Various aspects of the present disclosure are described herein with reference to flowcharts and/or block diagrams of methods, apparatuses, devices, and computer program products implemented according to the present disclosure. It should be understood that each block of the flowcharts and/or block diagrams and the combination of blocks in the flowcharts and/or block diagrams may be implemented by computer-readable program instructions.

These computer-readable program instructions may be provided to a processing unit of a general-purpose computer, a special-purpose computer, or other programmable data processing apparatus, so as to produce a machine, such that the instructions, when executed by the processing unit of the computer or other programmable data processing apparatus, produce an apparatus for implementing the functions/actions specified in one or more blocks of the flowcharts and/or block diagrams. These computer-readable program instructions may also be stored in a computer-readable storage medium. These instructions cause a computer, a programmable data processing apparatus, and/or other devices to work in a specific manner, so that the computer-readable medium on which the instructions are stored includes an article of manufacture, which includes instructions for implementing various aspects of the functions/actions specified in one or more blocks of the flowcharts and/or block diagrams.

The computer-readable program instructions may be loaded onto a computer, other programmable data processing apparatus, or other device, such that a series of operational steps are performed on the computer, other programmable data processing apparatus, or other device to produce a computer-implemented process, such that the instructions executed on the computer, other programmable data processing apparatus, or other device implement the functions/actions specified in one or more blocks of the flowcharts and/or block diagrams.

The flowcharts and block diagrams in the drawings show possible architectures, functions, and operations of the system, method, and computer program product implemented according to a plurality of implementations of the present disclosure. In this regard, each block in the flowcharts or block diagrams may represent a module, a program segment, or a portion of instructions, where the module, program segment, or portion of instructions includes one or more executable instructions for implementing specified logical functions. In some alternative implementations, the functions marked in the blocks may also occur in an order different from those marked in the drawings. For example, two consecutive blocks may actually be executed substantially in parallel, or they may sometimes be executed in a reverse order, depending on the functions involved. It should also be noted that each block in the block diagrams and/or flowcharts and the combination of blocks in the block diagrams and/or flowcharts may be implemented by a dedicated hardware-based system that performs the specified functions or actions, or may be implemented by a combination of dedicated hardware and computer instructions.

Various implementations of the present disclosure have been described above, and the above description is illustrative, not exhaustive, and is not limited to the disclosed implementations. Many modifications and changes will be apparent to those of ordinary skill in the art without departing from the scope and spirit of the described implementations. The choice of terms used herein is intended to best explain the principles, practical applications, or improvements of the technology in the market of the implementations, or to enable other ordinary skilled in the art to understand the implementations disclosed herein.

1-10. (canceled)

11. A method for evaluating a clock tree, comprising:
automatically determining a candidate clock tree structure for a clock tree based on a set of structural parameters for a plurality of portions of the clock tree, each structural parameter of the set of structural parameters being configured to define a structure of one of the plurality of portions;
obtaining circuit configuration information associated with the candidate clock tree structure, the circuit configuration information indicating connection relationships of circuit units in the candidate clock tree structure; and
determining a clock performance of the candidate clock tree structure based at least on the circuit configuration information.

12. The method according to claim 11, wherein determining the candidate clock tree structure comprises:
in response to at least one structural parameter in the set of structural parameters having different parameter values, determining a plurality of structural parameter combinations, each structural parameter combination comprising a set of parameter values for defining the plurality of portions;
determining a plurality of clock tree structures for the clock tree respectively based on the plurality of structural parameter combinations; and
configuring the plurality of clock tree structures as the candidate clock tree structure respectively.

13. The method according to claim 12, further comprising:
presenting the clock performance that is respectively determined for the plurality of clock tree structures.

14. The method according to claim 12, wherein determining the plurality of clock tree structures respectively comprises:
determining, for a given structural parameter combination among the plurality of structural parameter combinations, respective structures of the plurality of portions; and
determining a clock tree structure, from among the plurality of clock tree structures, that corresponds to the given structural parameter combination based on the respective structures of the plurality of portions and a relative relationship between the plurality of portions.

15. The method according to claim 11, further comprising:
providing, for at least one portion of the plurality of portions, a user interface for structure configuration; and
receiving, via the user interface, at least one parameter in the set of structural parameters, the at least one parameter corresponding to the at least one portion respectively.

16. The method according to claim 15, wherein the at least one portion comprises at least one of:
a clock mesh, configured to transmit a clock signal to a timing unit,
a mesh drive stage, configured to drive the clock mesh, or
a tap drive stage, configured to couple the clock mesh to the timing unit.

17. The method according to claim 11, wherein the plurality of portions comprises a clock mesh configured to transmit a clock signal to a timing unit, and wherein the clock performance is determined further based on a parasitic electrical parameter in the candidate clock tree structure.

18. An electronic device, comprising:
at least one processor; and
at least one memory coupled to the at least one processor and storing instructions for execution by the at least one processor, the instructions, when executed by the at least one processor, causing the electronic device to perform acts comprising:
automatically determining a candidate clock tree structure for a clock tree based on a set of structural parameters for a plurality of portions of the clock tree, each structural parameter of the set of structural parameters being configured to define a structure of one of the plurality of portions;
obtaining circuit configuration information associated with the candidate clock tree structure, the circuit configuration information indicating connection relationships of circuit units in the candidate clock tree structure; and
determining a clock performance of the candidate clock tree structure based at least on the circuit configuration information.

19. The electronic device according to claim 18, wherein determining the candidate clock tree structure comprises:
in response to at least one structural parameter in the set of structural parameters having different parameter values, determining a plurality of structural parameter combinations, each structural parameter combination comprising a set of parameter values for defining the plurality of portions;
determining a plurality of clock tree structures for the clock tree respectively based on the plurality of structural parameter combinations; and
configuring the plurality of clock tree structures as the candidate clock tree structure respectively.

20. The electronic device according to claim 19, wherein the acts further comprise:
presenting the clock performance that is respectively determined for the plurality of clock tree structures.

21. The electronic device according to claim 19, wherein determining the plurality of clock tree structures respectively comprises:
determining, for a given structural parameter combination among the plurality of structural parameter combinations, respective structures of the plurality of portions; and
determining a clock tree structure, from among the plurality of clock tree structures, that corresponds to the given structural parameter combination based on the respective structures of the plurality of portions and a relative relationship between the plurality of portions.

22. The electronic device according to claim 18, wherein the acts further comprise:
providing, for at least one portion of the plurality of portions, a user interface for structure configuration; and
receiving, via the user interface, at least one parameter in the set of structural parameters, the at least one parameter corresponding to the at least one portion respectively.

23. The electronic device according to claim 22, wherein the at least one portion comprises at least one of:
a clock mesh, configured to transmit a clock signal to a timing unit,
a mesh drive stage, configured to drive the clock mesh, or
a tap drive stage, configured to couple the clock mesh to the timing unit.

24. The electronic device according to claim 18, wherein the plurality of portions comprises a clock mesh configured to transmit a clock signal to a timing unit, and wherein the clock performance is determined further based on a parasitic electrical parameter in the candidate clock tree structure.

25. A non-transitory computer-readable storage medium, on which a computer program is stored, the computer program being executable by a processor to perform acts comprising:
automatically determining a candidate clock tree structure for a clock tree based on a set of structural parameters for a plurality of portions of the clock tree, each structural parameter of the set of structural parameters being configured to define a structure of one of the plurality of portions;
obtaining circuit configuration information associated with the candidate clock tree structure, the circuit configuration information indicating connection relationships of circuit units in the candidate clock tree structure; and
determining a clock performance of the candidate clock tree structure based at least on the circuit configuration information.

26. The non-transitory computer-readable storage medium according to claim 25, wherein determining the candidate clock tree structure comprises:
in response to at least one structural parameter in the set of structural parameters having different parameter values, determining a plurality of structural parameter combinations, each structural parameter combination comprising a set of parameter values for defining the plurality of portions;
determining a plurality of clock tree structures for the clock tree respectively based on the plurality of structural parameter combinations; and
configuring the plurality of clock tree structures as the candidate clock tree structure respectively.

27. The non-transitory computer-readable storage medium according to claim 26, wherein the acts further comprise:
presenting the clock performance that is respectively determined for the plurality of clock tree structures.

28. The non-transitory computer-readable storage medium according to claim 26, wherein determining the plurality of clock tree structures respectively comprises:
determining, for a given structural parameter combination among the plurality of structural parameter combinations, respective structures of the plurality of portions; and
determining a clock tree structure, from among the plurality of clock tree structures, that corresponds to the given structural parameter combination based on the respective structures of the plurality of portions and a relative relationship between the plurality of portions.

29. The non-transitory computer-readable storage medium according to claim 25, wherein the acts further comprise:
providing, for at least one portion of the plurality of portions, a user interface for structure configuration; and
receiving, via the user interface, at least one parameter in the set of structural parameters, the at least one parameter corresponding to the at least one portion respectively.

30. The non-transitory computer-readable storage medium according to claim 29, wherein the at least one portion comprises at least one of:
a clock mesh, configured to transmit a clock signal to a timing unit,
a mesh drive stage, configured to drive the clock mesh, or
a tap drive stage, configured to couple the clock mesh to the timing unit.
